(19) United States
(12) Patent Application Publication
(10) Pub. No.: US 2025/0077749 A1
(43) Pub. Date: Mar. 6, 2025

(54) SIMULATION-ASSISTED, MACHINE-LEARNING SOLUTION TO PROVIDE OILFIELD SUSTAINABILITY

(71) Applicant: Schlumberger Technology Corporation, Sugar Land, TX (US)

(72) Inventors: Maria Perezhogina, Houston, TX (US); Amir Shamsa, Calgary (CA)

(21) Appl. No.: 18/820,601

(22) Filed: Aug. 30, 2024

Related U.S. Application Data
(60) Provisional application No. 63/579,996, filed on Sep. 1, 2023.

(51) Int. Cl. G06F 30/28; G06F 30/27

(52) U.S. Cl. CPC G06F 30/28; G06F 30/27

(57) ABSTRACT

A method for predicting a likelihood that a physical phenomenon will occur in an area of interest at a wellsite includes receiving input parameters for a well in the area of interest. The method also includes generating or updating a geomodel based upon the input parameters. The geomodel includes a first model or a second model. The method also includes predicting a pressure result using the geomodel. The pressure result is based upon the input parameters. The method also includes predicting the likelihood that the physical phenomenon will occur in the future in the area of interest based upon the pressure results. The likelihood that the physical phenomenon will occur is predicted using a third model that is different than the first and second models.

### CROSS-REFERENCE TO RELATED APPLICATIONS

This application claims priority to U.S. Provisional Patent Application No. 63/579,996, filed on Sep. 1, 2023, which is incorporated by reference.

### BACKGROUND

In today's fast-paced world, technology is evolving at an unprecedented rate, and a digital transformation is taking place across various industries. The migration of software packages from conventional, on-premise systems to cloud-based platforms has been one of the most dramatic developments seen in recent years. To do so, users link multiple software packages together using programming and computer knowledge, which is time-consuming. There is currently no way to bridge the gap between these various platforms, allowing customers to take maximum advantage of cloud-based technologies.

More particularly, the integration of a standalone application such as Petrel® and simulation engines (SEs) has been implemented for several years. However, this approach is missing a component of data science modeling to boost functionality and performance. Connections between cloud-based data science applications and SEs have recently been introduced. However, these solutions are available to users with coding skills and do not offer an interface for graphical visualization or modifying simulation parameters. As there is no straightforward solution for end users without coding skills, many engineers are falling behind in the rapidly evolving field of machine learning (ML).

### SUMMARY

A method for predicting a likelihood that a physical phenomenon will occur in an area of interest at a wellsite is disclosed. The method includes receiving input parameters for a well in the area of interest. The method also includes generating or updating a geomodel based upon the input parameters. The geomodel includes a first model or a second model. The first model includes a simulation engine and an intermediary data science engine. The second model is a pre-trained machine-learning model. The method also includes predicting a pressure result using the geomodel. The pressure result is based upon the input parameters. The pressure result is predicted by the simulation engine upon completion of a simulation process, and subsequently monitored and checked by the intermediary data science engine in response to the geomodel being the first model. Alternatively, the pressure result is predicted by the second model run by the intermediary data science engine in response to the geomodel being the second model. The method also includes predicting the likelihood that the physical phenomenon will occur in the future in the area of interest based upon the pressure results. The likelihood that the physical phenomenon will occur is predicted using a third model that is different than the first and second models.

A computing system is also disclosed. The computing system includes one or more processors and a memory system coupled to the one or more processors. The memory system includes one or more non-transitory computer-readable media storing instructions that, when executed by at least one of the one or more processors, cause the computing system to perform operations. The operations include receiving input parameters for a well in an area of interest. The input parameters include historical physical phenomenon event data, user input data, and historical pressure and injection data. The historical physical phenomenon event data includes land subsidence, earthquakes, collapsing of subsurface cavities, compaction of loose deposits, faults, or a combination thereof. The user input data includes a location of the well, an injection rate into the well, a bottom hole pressure in the well, or a combination thereof. The historical pressure and injection data includes injection rates into a plurality of wells in the area of interest, bottom hole pressures in the plurality of wells, or both. The operations also include generating or updating a geomodel based upon the input parameters. The geomodel includes a proxy machine-learning model. The proxy machine-learning model includes a pre-trained Py-Torch machine-learning model. The proxy machine-learning model includes a physics-based neural network that includes a loss function. The loss function is based upon a data loss and a physics loss. The operations also include predicting a pressure result using the geomodel. The pressure result is based upon the input parameters. The pressure result is predicted by the proxy machine-learning model run by a data science engine. The operations also include predicting a likelihood that a physical phenomenon will occur in the future in the area of interest based upon the pressure results and the historical physical phenomenon event data. The likelihood that the physical phenomenon will occur is predicted using a different pre-trained machine-learning model.

A non-transitory, computer-readable medium is also disclosed. The medium stores instructions that, when executed by at least one processor of a computing system, cause the computing system to perform operations. The operations include receiving input parameters for a well in an area of interest. The input parameters include historical physical phenomenon event data, user input data, and historical pressure and injection data. The historical physical phenomenon event data includes land subsidence, earthquakes, collapsing of subsurface cavities, and compaction of loose deposits, faults. The user input data includes a location of the well, an injection rate into the well, and a bottom hole pressure in the well. The historical pressure and injection data includes injection rates into a plurality of wells in the area of interest and bottom hole pressures in the plurality of wells. The operations also include generating or updating a geomodel based upon the input parameters. The geomodel includes a proxy machine-learning model. The proxy machine-learning model is a pre-trained Py-Torch machine-learning model. The proxy machine-learning model is a physics-based neural network that includes a loss function. The loss function is based upon a data loss and a physics loss. The operations also include predicting a pressure result using the geomodel. The pressure result is based upon the input parameters. The pressure result is predicted by the proxy machine-learning model run by a data science engine. The operations also include predicting a likelihood that a physical phenomenon will occur in the future in the area of interest based upon the pressure results and the historical physical phenomenon event data. The likelihood that the physical phenomenon will occur is predicted using a different pre-trained machine-learning model. The operations also include generating a tree map and a heat map based upon the likelihood. The heat map shows the likelihood that the physical phenomenon will occur at a plurality of locations in the area of interest. The operations also include performing a wellsite action based upon the heat map, the tree map, or both to mitigate a risk created by the physical phenomenon occurring, wherein the wellsite action includes varying an injection rate, varying injection pressure into the well, or drilling a different well elsewhere in the area of interest.

This summary is provided to introduce a selection of concepts that are further described below in the detailed description. This summary is not intended to identify key or essential features of the claimed subject matter, nor is it intended to be used as an aid in limiting the scope of the claimed subject matter.

### BRIEF DESCRIPTION OF THE DRAWINGS

The accompanying drawings, which are incorporated in and constitute a part of this specification, illustrate embodiments of the present teachings and together with the description, serve to explain the principles of the present teachings. In the figures:

FIGS. 1A, 1B, 1C, 1D, 2, 3A, and 3B illustrate simplified, schematic views of an oilfield and its operation, according to an embodiment.

FIG. 4 illustrates a schematic view of an integrated workflow system that links a SE with a visualization web application via an intermediary data science (DS) engine, according to an embodiment.

FIG. 5 illustrates a schematic view of another integrated workflow, according to an embodiment.

FIG. 6 illustrates a flowchart of a method for integrating a simulation engine with a visualization web application via an intermediary data science engine within a cloud environment, according to an embodiment.

FIG. 7 illustrates a schematic view that shows the end-to-end solution provided in FIG. 6, according to an embodiment.

FIG. 8 illustrates a schematic view of the wellsite including updates to the (e.g., current) well and the addition of a (e.g., new) well, according to an embodiment.

FIG. 9 illustrates workflows that may be performed by the model, according to an embodiment.

FIG. 10A illustrates a plurality of input parameters, FIG. 10B illustrates previous physical phenomenon in the area of interest, and FIG. 10C illustrates predicted physical phenomenon in the area of interest, according to an embodiment.

FIG. 11 illustrates a computing system for performing at least a portion of the method(s) disclosed herein, according to an embodiment.

### DETAILED DESCRIPTION

Reference will now be made in detail to embodiments, examples of which are illustrated in the accompanying drawings and figures. In the following detailed description, numerous specific details are set forth in order to provide a thorough understanding of the invention. However, it will be apparent to one of ordinary skill in the art that the invention may be practiced without these specific details. In other instances, well-known methods, procedures, components, circuits and networks have not been described in detail so as not to unnecessarily obscure aspects of the embodiments.

It will also be understood that, although the terms first, second, etc. may be used herein to describe various elements, these elements should not be limited by these terms. These terms are only used to distinguish one element from another. For example, a first object could be termed a second object, and, similarly, a second object could be termed a first object, without departing from the scope of the invention. The first object and the second object are both objects, respectively, but they are not to be considered the same object.

The terminology used in the description of the invention herein is for the purpose of describing particular embodiments only and is not intended to be limiting of the invention. As used in the description of the invention and the appended claims, the singular forms “a,” “an” and “the” are intended to include the plural forms as well, unless the context clearly indicates otherwise. It will also be understood that the term “and/or” as used herein refers to and encompasses any possible combinations of one or more of the associated listed items. It will be further understood that the terms “includes,” “including,” “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, as used herein, the term “if” may be construed to mean “when” or “upon” or “in response to determining” or “in response to detecting,” depending on the context.

Attention is now directed to processing procedures, methods, techniques and workflows that are in accordance with some embodiments. Some operations in the processing procedures, methods, techniques and workflows disclosed herein may be combined and/or the order of some operations may be changed.

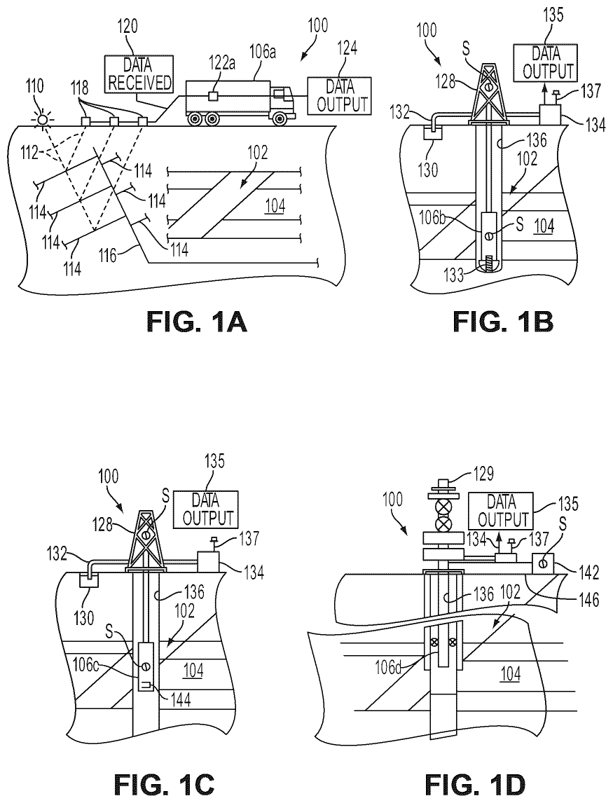

FIGS. 1A-1D illustrate simplified, schematic views of oilfield 100 having subterranean formation 102 containing reservoir 104 therein in accordance with implementations of various technologies and techniques described herein. Although embodiments of the present method are at least partially described herein with reference to an oilfield, it will be appreciated that this is merely an illustrative example. Embodiments of the present method may be employed in any application in which visualizing, modeling, or otherwise identifying subsurface features (e.g., geological features) may be useful. Examples outside of the oilfield context include subsurface mapping for wind arrays and/or solar arrays, geothermal energy production, mining operations, offshore/deep ocean applications, etc.

FIG. 1A illustrates a survey operation being performed by a survey tool, such as seismic truck 106.1, to measure properties of the subterranean formation. The survey operation is a seismic survey operation for producing sound vibrations. In FIG. 1A, one such sound vibration, e.g., sound vibration 112 generated by source 110, reflects off horizons 114 in earth formation 116. A set of sound vibrations is received by sensors, such as geophone-receivers 118, situated on the earth's surface. The data received 120 is provided as input data to a computer 122.1 of a seismic truck 106.1, and responsive to the input data, computer 122.1 generates seismic data output 124. This seismic data output may be stored, transmitted or further processed as desired, for example, by data reduction.

FIG. 1B illustrates a drilling operation being performed by drilling tools 106.2 suspended by rig 128 and advanced into subterranean formations 102 to form wellbore 136. Mud pit 130 is used to draw drilling mud into the drilling tools via flow line 132 for circulating drilling mud down through the drilling tools, then up wellbore 136 and back to the surface. The drilling mud is typically filtered and returned to the mud pit. A circulating system may be used for storing, controlling, or filtering the flowing drilling mud. The drilling tools are advanced into subterranean formations 102 to reach reservoir 104. Each well may target one or more reservoirs. The drilling tools are adapted for measuring downhole properties using logging while drilling tools. The logging while drilling tools may also be adapted for taking core sample 133 as shown.

Computer facilities may be positioned at various locations about the oilfield 100 (e.g., the surface unit 134) and/or at remote locations. Surface unit 134 may be used to communicate with the drilling tools and/or offsite operations, as well as with other surface or downhole sensors. Surface unit 134 is capable of communicating with the drilling tools to send commands to the drilling tools, and to receive data therefrom. Surface unit 134 may also collect data generated during the drilling operation and produce data output 135, which may then be stored or transmitted.

Sensors (S), such as gauges, may be positioned about oilfield 100 to collect data relating to various oilfield operations as described previously. As shown, sensor (S) is positioned in one or more locations in the drilling tools and/or at rig 128 to measure drilling parameters, such as weight on bit, torque on bit, pressures, temperatures, flow rates, compositions, rotary speed, and/or other parameters of the field operation. Sensors (S) may also be positioned in one or more locations in the circulating system.

Drilling tools 106.2 may include a bottom hole assembly (BHA) (not shown), generally referenced, near the drill bit (e.g., within several drill collar lengths from the drill bit). The bottom hole assembly includes capabilities for measuring, processing, and storing information, as well as communicating with surface unit 134. The bottom hole assembly further includes drill collars for performing various other measurement functions.

The bottom hole assembly may include a communication subassembly that communicates with surface unit 134. The communication subassembly is adapted to send signals to and receive signals from the surface using a communications channel such as mud pulse telemetry, electro-magnetic telemetry, or wired drill pipe communications. The communication subassembly may include, for example, a transmitter that generates a signal, such as an acoustic or electromagnetic signal, which is representative of the measured drilling parameters. It will be appreciated by one of skill in the art that a variety of telemetry systems may be employed, such as wired drill pipe, electromagnetic or other known telemetry systems.

Typically, the wellbore is drilled according to a drilling plan that is established prior to drilling. The drilling plan typically sets forth equipment, pressures, trajectories and/or other parameters that define the drilling process for the wellsite. The drilling operation may then be performed according to the drilling plan. However, as information is gathered, the drilling operation may need to deviate from the drilling plan. Additionally, as drilling or other operations are performed, the subsurface conditions may change. The earth model may also need adjustment as new information is collected

The data gathered by sensors (S) may be collected by surface unit 134 and/or other data collection sources for analysis or other processing. The data collected by sensors (S) may be used alone or in combination with other data. The data may be collected in one or more databases and/or transmitted on or offsite. The data may be historical data, real time data, or combinations thereof. The real time data may be used in real time, or stored for later use. The data may also be combined with historical data or other inputs for further analysis. The data may be stored in separate databases, or combined into a single database.

Surface unit 134 may include transceiver 137 to allow communications between surface unit 134 and various portions of the oilfield 100 or other locations. Surface unit 134 may also be provided with or functionally connected to one or more controllers (not shown) for actuating mechanisms at oilfield 100. Surface unit 134 may then send command signals to oilfield 100 in response to data received. Surface unit 134 may receive commands via transceiver 137 or may itself execute commands to the controller. A processor may be provided to analyze the data (locally or remotely), make the decisions and/or actuate the controller. In this manner, oilfield 100 may be selectively adjusted based on the data collected. This technique may be used to optimize (or improve) portions of the field operation, such as controlling drilling, weight on bit, pump rates, or other parameters. These adjustments may be made automatically based on computer protocol, and/or manually by an operator. In some cases, well plans may be adjusted to select optimum (or improved) operating conditions, or to avoid problems.

FIG. 1C illustrates a wireline operation being performed by wireline tool 106.3 suspended by rig 128 and into wellbore 136 of FIG. 1B. Wireline tool 106.3 is adapted for deployment into wellbore 136 for generating well logs, performing downhole tests and/or collecting samples. Wireline tool 106.3 may be used to provide another method and apparatus for performing a seismic survey operation. Wireline tool 106.3 may, for example, have an explosive, radioactive, electrical, or acoustic energy source 144 that sends and/or receives electrical signals to surrounding subterranean formations 102 and fluids therein.

Wireline tool 106.3 may be operatively connected to, for example, geophones 118 and a computer 122.1 of a seismic truck 106.1 of FIG. 1A. Wireline tool 106.3 may also provide data to surface unit 134. Surface unit 134 may collect data generated during the wireline operation and may produce data output 135 that may be stored or transmitted. Wireline tool 106.3 may be positioned at various depths in the wellbore 136 to provide a survey or other information relating to the subterranean formation 102.

Sensors (S), such as gauges, may be positioned about oilfield 100 to collect data relating to various field operations as described previously. As shown, sensor S is positioned in wireline tool 106.3 to measure downhole parameters which relate to, for example porosity, permeability, fluid composition and/or other parameters of the field operation.

FIG. 1D illustrates a production operation being performed by production tool 106.4 deployed from a production unit or Christmas tree 129 and into completed wellbore 136 for drawing fluid from the downhole reservoirs into surface facilities 142. The fluid flows from reservoir 104 through perforations in the casing (not shown) and into production tool 106.4 in wellbore 136 and to surface facilities 142 via gathering network 146.

Sensors (S), such as gauges, may be positioned about oilfield 100 to collect data relating to various field operations as described previously. As shown, the sensor (S) may be positioned in production tool 106.4 or associated equipment, such as Christmas tree 129, gathering network 146, surface facility 142, and/or the production facility, to measure fluid parameters, such as fluid composition, flow rates, pressures, temperatures, and/or other parameters of the production operation.

Production may also include injection wells for added recovery. One or more gathering facilities may be operatively connected to one or more of the wellsites for selectively collecting downhole fluids from the wellsite(s).

While FIGS. 1B-1D illustrate tools used to measure properties of an oilfield, it will be appreciated that the tools may be used in connection with non-oilfield operations, such as gas fields, mines, aquifers, storage or other subterranean facilities. Also, while certain data acquisition tools are depicted, it will be appreciated that various measurement tools capable of sensing parameters, such as seismic two-way travel time, density, resistivity, production rate, etc., of the subterranean formation and/or its geological formations may be used. Various sensors (S) may be located at various positions along the wellbore and/or the monitoring tools to collect and/or monitor the desired data. Other sources of data may also be provided from offsite locations.

The field configurations of FIGS. 1A-1D are intended to provide a brief description of an example of a field usable with oilfield application frameworks. Part of, or the entirety, of oilfield 100 may be on land, water and/or sea. Also, while a single field measured at a single location is depicted, oilfield applications may be utilized with any combination of one or more oilfields, one or more processing facilities and one or more wellsites.

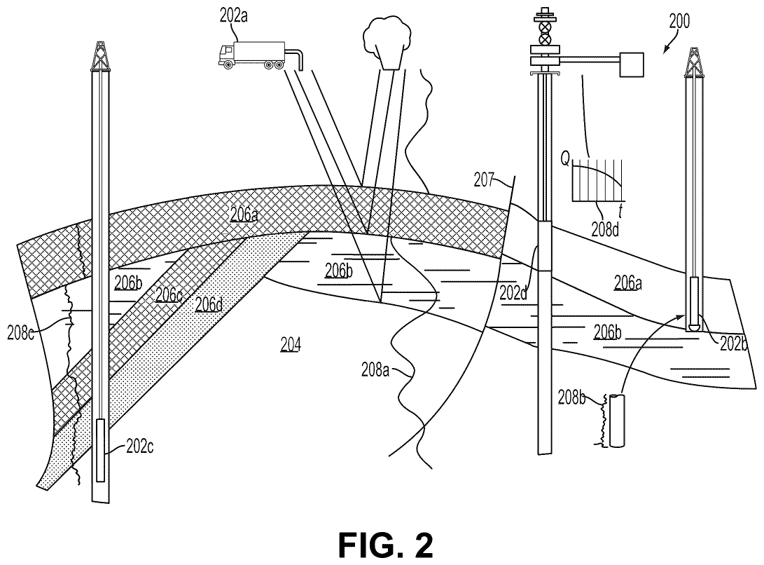

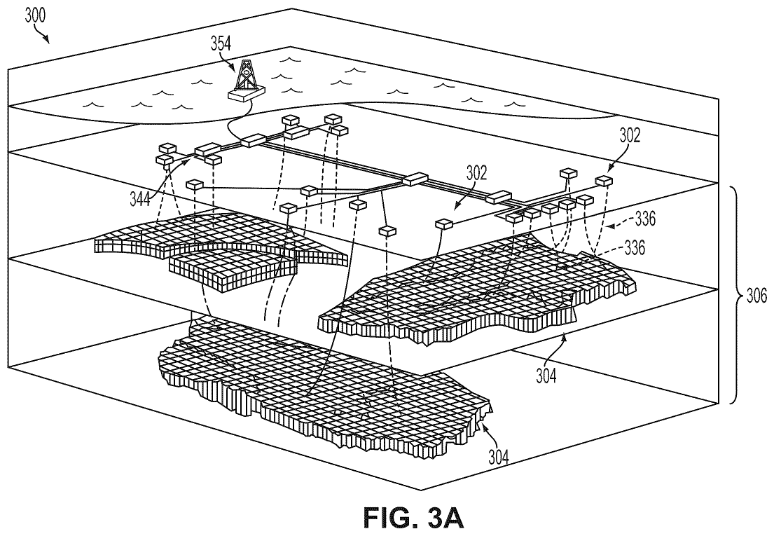

FIG. 2 illustrates a schematic view, partially in cross section of oilfield 200 having data acquisition tools 202.1, 202.2, 202.3 and 202.4 positioned at various locations along oilfield 200 for collecting data of subterranean formation 204 in accordance with implementations of various technologies and techniques described herein. Data acquisition tools 202.1-202.4 may be the same as data acquisition tools 106.1-106.4 of FIGS. 1A-ID, respectively, or others not depicted. As shown, data acquisition tools 202.1-202.4 generate data plots or measurements 208.1-208.4, respectively. These data plots are depicted along oilfield 200 to demonstrate the data generated by the various operations.

Data plots 208.1-208.3 are examples of static data plots that may be generated by data acquisition tools 202.1-202.3, respectively; however, it should be understood that data plots 208.1-208.3 may also be data plots that are updated in real time. These measurements may be analyzed to better define the properties of the formation(s) and/or determine the accuracy of the measurements and/or for checking for errors. The plots of each of the respective measurements may be aligned and scaled for comparison and verification of the properties.

Static data plot 208.1 is a seismic two-way response over a period of time. Static plot 208.2 is core sample data measured from a core sample of the formation 204. The core sample may be used to provide data, such as a graph of the density, porosity, permeability, or some other physical property of the core sample over the length of the core. Tests for density and viscosity may be performed on the fluids in the core at varying pressures and temperatures. Static data plot 208.3 is a logging trace that typically provides a resistivity or other measurement of the formation at various depths.

A production decline curve or graph 208.4 is a dynamic data plot of the fluid flow rate over time. The production decline curve typically provides the production rate as a function of time. As the fluid flows through the wellbore, measurements are taken of fluid properties, such as flow rates, pressures, composition, etc.

Other data may also be collected, such as historical data, user inputs, economic information, and/or other measurement data and other parameters of interest. As described below, the static and dynamic measurements may be analyzed and used to generate models of the subterranean formation to determine characteristics thereof. Similar measurements may also be used to measure changes in formation aspects over time.

The subterranean structure 204 has a plurality of geological formations 206.1-206.4. As shown, this structure has several formations or layers, including a shale layer 206.1, a carbonate layer 206.2, a shale layer 206.3 and a sand layer 206.4. A fault 207 extends through the shale layer 206.1 and the carbonate layer 206.2. The static data acquisition tools are adapted to take measurements and detect characteristics of the formations.

While a specific subterranean formation with specific geological structures is depicted, it will be appreciated that oilfield 200 may contain a variety of geological structures and/or formations, sometimes having extreme complexity. In some locations, typically below the water line, fluid may occupy pore spaces of the formations. Each of the measurement devices may be used to measure properties of the formations and/or its geological features. While each acquisition tool is shown as being in specific locations in oilfield 200, it will be appreciated that one or more types of measurement may be taken at one or more locations across one or more fields or other locations for comparison and/or analysis.

The data collected from various sources, such as the data acquisition tools of FIG. 2, may then be processed and/or evaluated. Typically, seismic data displayed in static data plot 208.1 from data acquisition tool 202.1 is used by a geophysicist to determine characteristics of the subterranean formations and features. The core data shown in static plot 208.2 and/or log data from well log 208.3 are typically used by a geologist to determine various characteristics of the subterranean formation. The production data from graph 208.4 is typically used by the reservoir engineer to determine fluid flow reservoir characteristics. The data analyzed by the geologist, geophysicist and the reservoir engineer may be analyzed using modeling techniques.

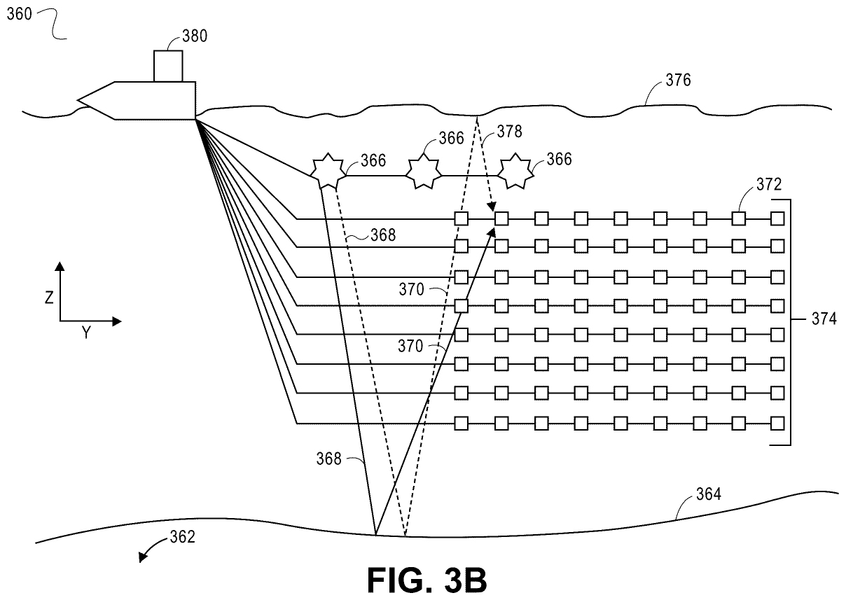

FIG. 3A illustrates an oilfield 300 for performing production operations in accordance with implementations of various technologies and techniques described herein. As shown, the oilfield has a plurality of wellsites 302 operatively connected to central processing facility 354. The oilfield configuration of FIG. 3A is not intended to limit the scope of the oilfield application system. Part, or all, of the oilfield may be on land and/or sea. Also, while a single oilfield with a single processing facility and a plurality of wellsites is depicted, any combination of one or more oilfields, one or more processing facilities and one or more wellsites may be present.

Each wellsite 302 has equipment that forms wellbore 336 into the earth. The wellbores extend through subterranean formations 306 including reservoirs 304. These reservoirs 304 contain fluids, such as hydrocarbons. The wellsites draw fluid from the reservoirs and pass them to the processing facilities via surface networks 344. The surface networks 344 have tubing and control mechanisms for controlling the flow of fluids from the wellsite to processing facility 354.

Attention is now directed to FIG. 3B, which illustrates a side view of a marine-based survey 360 of a subterranean subsurface 362 in accordance with one or more implementations of various techniques described herein. Subsurface 362 includes seafloor surface 364. Seismic sources 366 may include marine sources such as vibroseis or airguns, which may propagate seismic waves 368 (e.g., energy signals) into the Earth over an extended period of time or at a nearly instantaneous energy provided by impulsive sources. The seismic waves may be propagated by marine sources as a frequency sweep signal. For example, marine sources of the vibroseis type may initially emit a seismic wave at a low frequency (e.g., 5 Hz) and increase the seismic wave to a high frequency (e.g., 80-90 Hz) over time.

The component(s) of the seismic waves 368 may be reflected and converted by seafloor surface 364 (i.e., reflector), and seismic wave reflections 370 may be received by a plurality of seismic receivers 372. Seismic receivers 372 may be disposed on a plurality of streamers (i.e., streamer array 374). The seismic receivers 372 may generate electrical signals representative of the received seismic wave reflections 370. The electrical signals may be embedded with information regarding the subsurface 362 and captured as a record of seismic data.

In one implementation, each streamer may include streamer steering devices such as a bird, a deflector, a tail buoy and the like, which are not illustrated in this application. The streamer steering devices may be used to control the position of the streamers in accordance with the techniques described herein.

In one implementation, seismic wave reflections 370 may travel upward and reach the water/air interface at the water surface 376, a portion of reflections 370 may then reflect downward again (i.e., sea-surface ghost waves 378) and be received by the plurality of seismic receivers 372. The sea-surface ghost waves 378 may be referred to as surface multiples. The point on the water surface 376 at which the wave is reflected downward is generally referred to as the downward reflection point.

The electrical signals may be transmitted to a vessel 380 via transmission cables, wireless communication or the like. The vessel 380 may then transmit the electrical signals to a data processing center. Alternatively, the vessel 380 may include an onboard computer capable of processing the electrical signals (i.e., seismic data). Those skilled in the art having the benefit of this disclosure will appreciate that this illustration is highly idealized. For instance, surveys may be of formations deep beneath the surface. The formations may typically include multiple reflectors, some of which may include dipping events, and may generate multiple reflections (including wave conversion) for receipt by the seismic receivers 372. In one implementation, the seismic data may be processed to generate a seismic image of the subsurface 362.

Marine seismic acquisition systems tow each streamer in streamer array 374 at the same depth (e.g., 5-10 m). However, marine based survey 360 may tow each streamer in streamer array 374 at different depths such that seismic data may be acquired and processed in a manner that avoids the effects of destructive interference due to sea-surface ghost waves. For instance, marine-based survey 360 of FIG. 3B illustrates eight streamers towed by vessel 380 at eight different depths. The depth of each streamer may be controlled and maintained using the birds disposed on each streamer.

### Leveraging a Digital Platform to Create a Fully Automated, Simulation-Assisted, ML Solution to Provide Oilfield Sustainability

The present disclosure includes a system and method for seamlessly integrating machine learning (ML), simulation engines (SE), and web applications, while offering an intuitive user interface. More particularly, the present disclosure may link a SE with a visualization web application via an intermediary data science (DS) engine. The data science engine may be specifically designed for data analytics and ML applications. The system may be engineered to enhance the efficiency and effectiveness of data communication and processing across the components, while capitalizing on ML capabilities. Thus, the present disclosure represents an advancement in the technology integration within a cloud environment by enabling seamless, real-time processing, modeling, and data flow. Currently, there is no equivalent for this integrated solution in the industry.

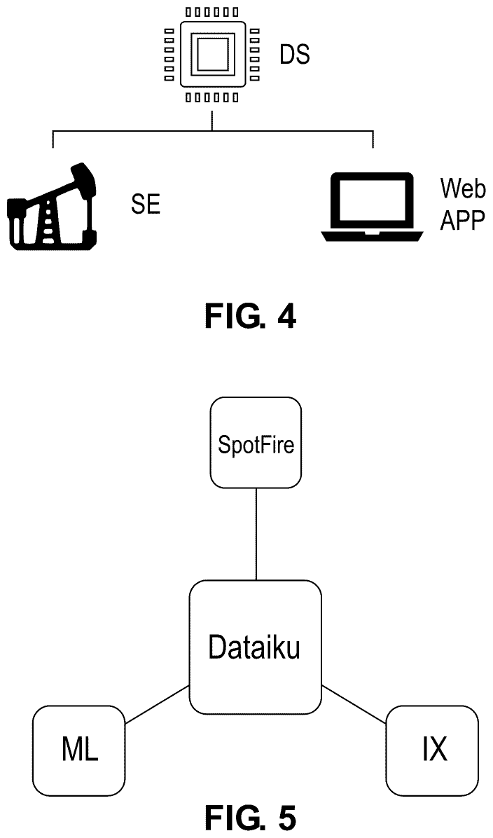

FIG. 4 illustrates a schematic view of an integrated workflow system that links a SE with a visualization web application via an intermediary data science (DS) engine, according to an embodiment. This robust solution with an intuitive user interface may include different components, models, and processes that work together to provide an effective and efficient pipeline. As illustrated in FIG. 4, the DS layer serves as the system's central processor unit. The DS component interacts with the user through the web application (Web App), updating each simulation case based on the user's inputs and providing the results for analysis and visualization. As soon as the inputs are received, the DS may translate the data into a predetermined format, create new features, launch SE, closely monitor the simulation's progress, apply ML to enhance the data, and push the output back to the web application for the visual analysis and quality control (QC).

FIG. 5 illustrates an exemplary embodiment of the technologies integrated within the workflow depicted in FIG. 4, according to an embodiment. In this embodiment, Dataiku functions as the central component of the Data Science (DS) layer, Spotfire serves as the Web Application (Web App) interface, IX (SLB Intersect) operates as the simulation engine (SE), and Machine Learning (ML) extends the Data Science (DS) layer to enhance overall functionality.

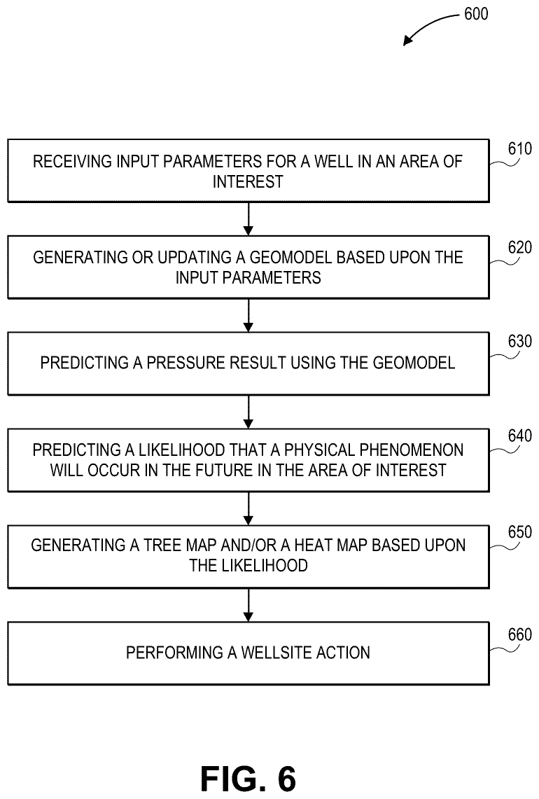

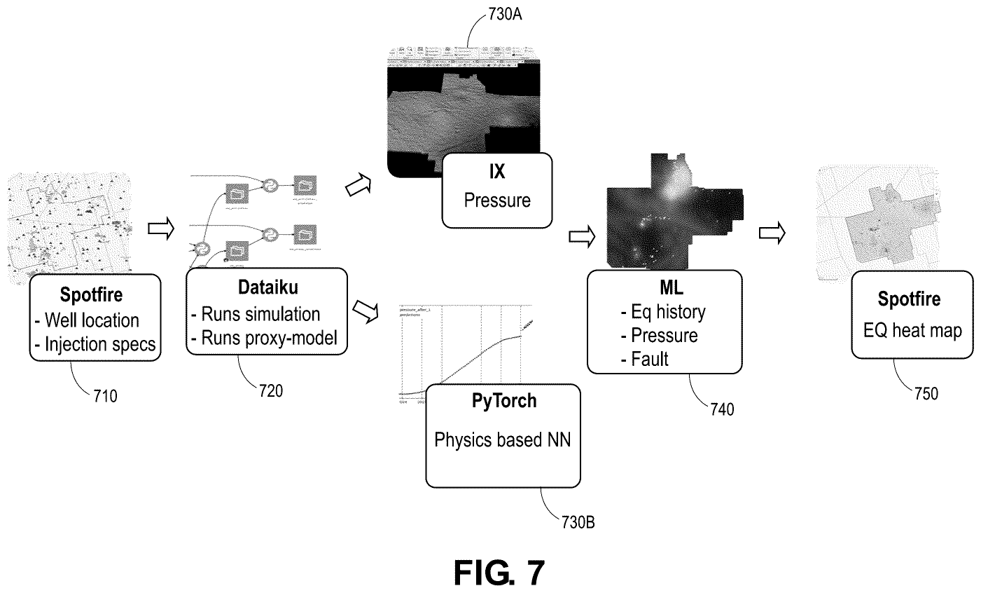

FIG. 6 illustrates a flowchart of a method 600 for integrating a simulation engine with a visualization web application via an intermediary data science engine within a cloud environment, according to an embodiment. The method 600 may be used for predicting a likelihood that a physical phenomenon will occur in an area of interest at a wellsite. An illustrative order of the method 600 is provided below; however, one or more portions of the method 600 may be performed in a different order, simultaneously, repeated, or omitted. FIG. 7 illustrates a schematic view that shows the end-to-end solution provided in FIG. 6, according to an embodiment.

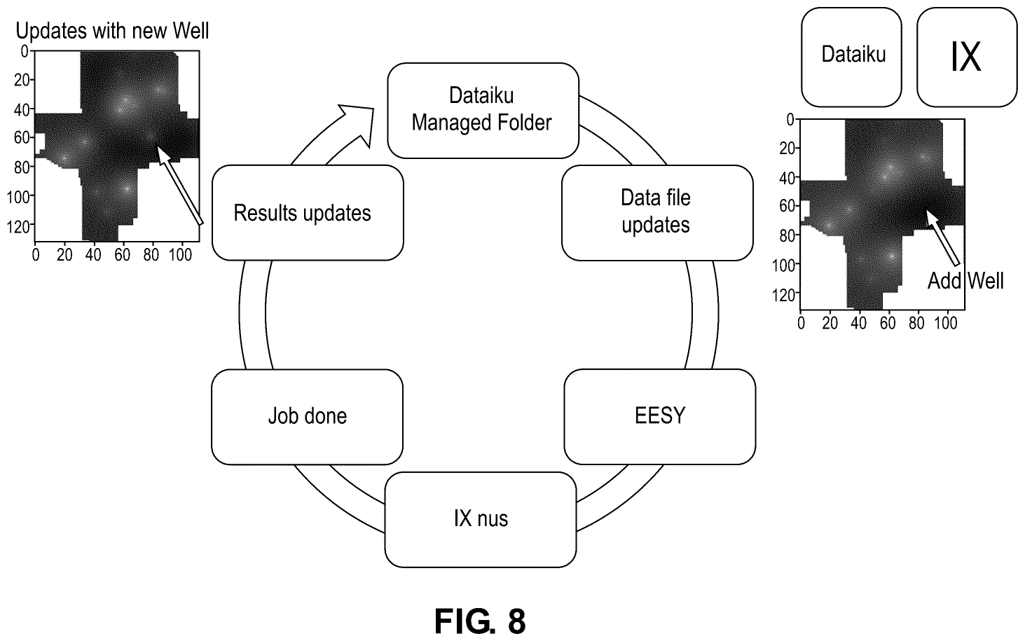

The method 600 may include receiving input parameters for a well in an area of interest, as at 610. This is also shown at 710 in FIG. 7. The input parameters may be received by the web application. The area of interest may be a portion of a subterranean formation at (e.g., below) a wellsite. The input parameters may be or include historical physical phenomenon event data, user input data, historical pressure and/or injection data, or a combination thereof. The historical physical phenomenon event data may be or include land subsidence, earthquakes, collapsing of subsurface cavities, compaction of loose deposits, faults, or a combination thereof. The user input data may be or include a location of the well (e.g., received by clicking on the map or entering coordinates manually), an injection rate into the well, a bottom hole pressure in the well, or a combination thereof. The well may be an injection well or a production well. FIG. 8 illustrates a schematic view of the wellsite including updates to the (e.g., current) well and the addition of a (e.g., new) well, according to an embodiment. The historical pressure and/or injection data may be or include injection rates into a plurality of wells in the area of interest and/or bottom hole pressures in the plurality of wells.

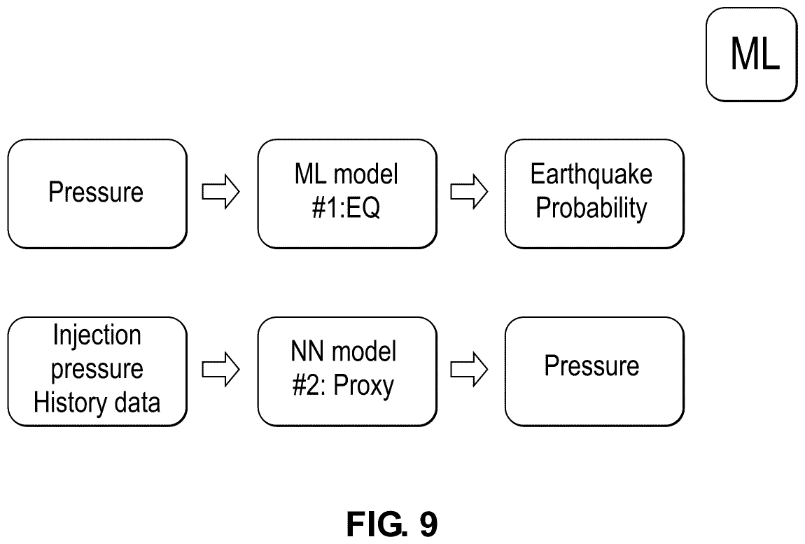

The method 600 may also include generating or updating a geomodel based upon the input parameters, as at 620. This is also shown at 720 in FIG. 7. The geomodel may be received (or generated or updated) by the web application. FIG. 9 illustrates workflows that may be performed by the geomodel, according to an embodiment.

The geomodel may be or include a first (e.g., simulation) model and/or a second (e.g., proxy machine-learning) model. The first (e.g., simulation) model may be or include a simulation engine and an intermediary data science engine. The second (e.g., proxy machine-learning) model may be or include a pre-trained Py-Torch machine-learning model. The second (e.g., proxy machine-learning) model may also or instead be or include a physics-based neural network that incorporates a pressure diffusion equation that simulates reservoir behavior by embedding physical laws directly into the model's architecture. This approach enhances prediction accuracy and reliability by ensuring that the model's outputs align with both empirical data and established physical principles, enabling more effective management of fluid dynamics in reservoirs for the area of interest. The neural network includes or uses a loss function that guides the neural network towards a final solution. The loss function components are shown below.

### Loss Function Components for Pressure Diffusion

### Data Loss

$${ℒ}_{data} - \frac{1}{N} {\sum }_{i = 1}^{N} {( P ( {t}_{i} , {x}_{i} ) - {P}_{data} ( {t}_{i} , {x}_{i} ) )}^{2}$$

P(tᵢ,xᵢ): The neural network's prediction of pressure at time tᵢ and spatial location Tᵢ (e.g., within a reservoir).
P_{data}(tᵢ,xᵢ): The actual observed pressure data at time tᵢ and spatial location xᵢ.

### Physics Loss

For pressure diffusion governed by the diffusion equation

$$\frac{\partial P}{\partial t} = D {∇}^{2} P :$$

$${ℒ}_{physics} = \frac{1}{M} {\sum }_{j = 1}^{M} {( \frac{\partial P ( {t}_{j} , {x}_{j} )}{\partial t} - D {∇}^{2} P ( {t}_{j} , {x}_{j} ) )}^{2}$$

D: Pressure diffusivity (related to permeability, viscosity, and porosity of the reservoir).
∇²P(tⱼ, xⱼ): Laplacian of pressure, representing the spatial diffusion of pressure within the reservoir.
   Total Loss Function: [symbol] ₜₒₜₐₗ− [symbol] _{data}+λ [symbol] _{physics}λ: Weighting factor that controls the balance between fitting the observed pressure data and satisfying the pressure diffusion equation.

Here's a brief explanation of the parameters in the loss function:
1. P(tᵢ, xᵢ): The neural network's prediction of pressure at time tᵢ and spatial location xᵢ within a reservoir.
2. P_{data}(tᵢ, xᵢ): The actual observed pressure data at time tᵢ and spatial location xᵢ.
3. D: Pressure diffusivity, which is influenced by the reservoir's permeability, fluid viscosity, and porosity.
4. ∇²P(tⱼ, xᵢ) Laplacian of the neural network's pressure prediction, representing spatial pressure diffusion within the reservoir.
5. N: Number of data points used to calculate the data loss (how well the model fits the observed pressure data).
6. M: Number of points used to enforce the physics-based constraints (PDE) n the physics loss (how well the model satisfies the pressure diffusion equation).
7. λ: Weighting factor that balances the importance between fitting the observed pressure data and satisfying the pressure diffusion equation in the total loss function.

As shown, the loss function may be based upon or include a data loss and/or a physics loss. More particularly, the loss function may be or include a summation of the data loss and a product. In an example, the product may be or include the physics loss multiplied by a weighting factor. The data loss may be based upon a prediction by the neural network at a predetermined time and a predetermined spatial position, observed or known data at the predetermined time and the predetermined spatial position, a first number of data points used to calculate the data loss, or a combination thereof. The physics loss may be based upon a diffusion coefficient, a Laplacian operator of the prediction by the neural network that represents spatial diffusion, a second number of data points used to enforce a partial differential equation in the physics loss, or a combination thereof.

In conventional neural networks (NNs), the model learns relationships purely from data, relying on large datasets to generalize and make predictions. These networks are data-driven, and the learning process is guided by optimizing a loss function, which measures the error between the predicted outputs and the actual data. Conventional NNs can struggle in scenarios where data is sparse, noisy, or where physical laws are to be respected. Physics-based neural networks (PNNs) integrate physical laws directly into the learning process. In the present disclosure, the equations of fluid flow and pressure behavior are incorporated into the PNN with a specific focus on reservoir simulation. In this way, the inputs are automatically updated with reservoir simulation results and updated historical data, and the outputs are sent to the Web APP for the risk evaluation. This integration allows the system to learn the dynamics of reservoir behavior in a manner consistent with established physical laws, improving both predictive accuracy and computational efficiency.

The method 600 may also include predicting a pressure result using the geomodel, as at 630. The pressure result may be based upon the input parameters. In one embodiment, the pressure result may be predicted by the simulation engine upon completion of a simulation process, and subsequently monitored and checked by the intermediary data science engine in response to the geomodel being the first (e.g., simulation) model. This is shown at 730A in FIG. 7. In another embodiment, the pressure result may be predicted by the second (e.g., proxy machine-learning) model run by the data science engine in response to the geomodel being the second (e.g., proxy machine-learning) model. This is shown at 730B in FIG. 7. An example of the pressure result may be similar to reference number 730A with less precision which is the result of faster processing.

The method 600 may also include predicting the likelihood that the physical phenomenon will occur in the future in the area of interest, as at 640. This is shown at 740 in FIG. 7. The likelihood may be predicted based upon the pressure results and/or the historical physical phenomenon event data (e.g., earthquake history, land subsidence). The likelihood that the physical phenomenon will occur may be predicted using a third (e.g., pre-trained ML) model that is different than the first and second models. The physical phenomenon may be or include land subsidence, earthquakes, collapsing of subsurface cavities, compaction of loose deposits, faults, or a combination thereof.

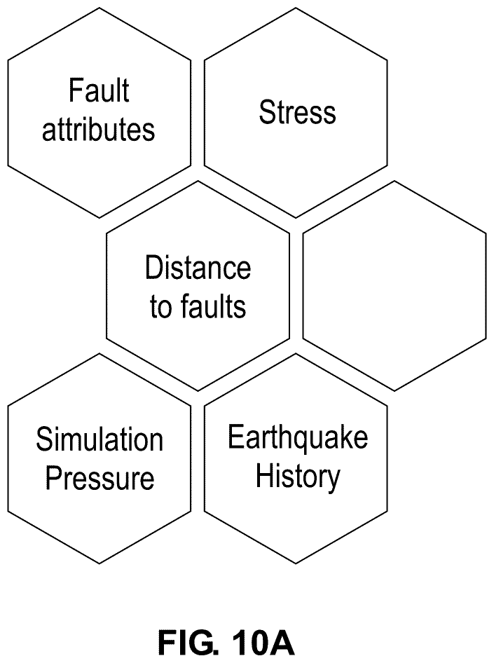

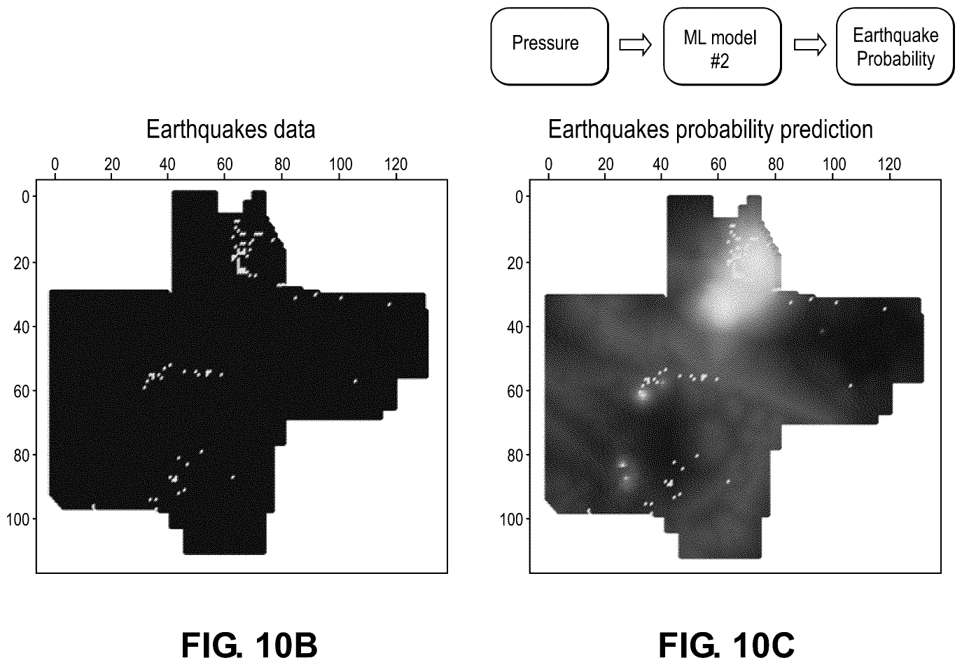

The method 600 may also include generating a tree map and/or a heat map based upon the likelihood, as at 650. This is shown at 750 in FIG. 7. The heat map shows the likelihood that the physical phenomenon will occur at a plurality of locations in the area of interest. FIG. 10A illustrates a plurality of input parameters, FIG. 10B illustrates previous physical phenomenon in the area of interest, and FIG. 10C illustrates a heat map showing predicted physical phenomenon (e.g., earthquakes) in the area of interest, according to an embodiment. The tree map may be or include the visualization of the modeled operation risk for the area of interest.

The method 600 may also include performing a wellsite action, as at 660. The wellsite action may be performed based upon or in response to the pressure result, the likelihood, the tree map, the heat map, or a combination thereof. The wellsite action may be or include generating and/or transmitting a signal (e.g., using a computing system) that instructs or causes a physical action to occur at a wellsite. The wellsite action may also or instead include performing the physical action at the wellsite. The wellsite action may mitigate a risk created by the physical phenomenon occurring. The physical action may include varying an injection rate or injection pressure into the well (or drilling a different well elsewhere). In another embodiment, the physical action may include selecting where to drill a wellbore, drilling the wellbore, varying a weight and/or torque on a drill bit that is drilling the wellbore, varying a drilling trajectory of the wellbore, varying a concentration and/or flow rate of a fluid pumped into the wellbore, or the like.

The system and method may provide integration, user accessibility, scalability, and enhanced data processing and analysis. There is currently no conventional system that successfully integrates SEs, ML platforms, and web applications in a cloud environment. Either web application layer or the data science layer is missing.

A wide range of potential users can effectively engage with the system and gain beneficial insight from the data as a result to the intuitive layout without having any additional programming or ML expertise. The system and method are easily scalable for various engineering simulations and applications. This adaptability allows users to manage multiple simulation scenarios, ML models, and dashboards. Additionally, the system and method can support a variety of attributes, time series, and spatial data.

The DS component enables data processing and analysis with the ML power. It may, for instance, pull simulation results, run ML analysis on them, and then deliver the modified data back to the user application. As a result, the system and method can give complex data analytics, enabling users to make informed decisions. In conclusion, the system and method add a DS layer to a simulation engine. The unique approach offers a comprehensive, scalable, user accessible system to enhance data processing, analysis, and overall user experience.

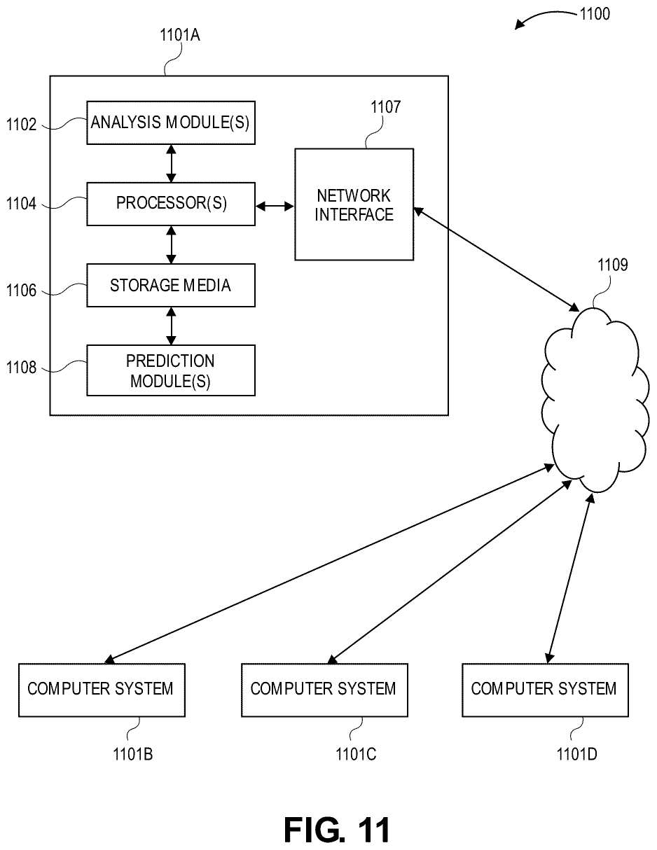

In some embodiments, any of the methods of the present disclosure may be executed by a computing system. FIG. 11 illustrates an example of such a computing system 1100, in accordance with some embodiments. The computing system 1100 may include a computer or computer system 1101A, which may be an individual computer system 1101A or an arrangement of distributed computer systems. The computer system 1101A includes one or more analysis module(s) 1102 configured to perform various tasks according to some embodiments, such as one or more methods disclosed herein. To perform these various tasks, the analysis module 1102 executes independently, or in coordination with, one or more processors 1104, which is (or are) connected to one or more storage media 1106. The processor(s) 1104 is (or are) also connected to a network interface 1107 to allow the computer system 1101A to communicate over a data network 1109 with one or more additional computer systems and/or computing systems, such as 1101B, 1101C, and/or 1101D (note that computer systems 1101B, 1101C and/or 1101D may or may not share the same architecture as computer system 1101A, and may be located in different physical locations, e.g., computer systems 1101A and 1101B may be located in a processing facility, while in communication with one or more computer systems such as 1101C and/or 1101D that are located in one or more data centers, and/or located in varying countries on different continents).

A processor can include a microprocessor, microcontroller, processor module or subsystem, programmable integrated circuit, programmable gate array, or another control or computing device.

The storage media 1106 can be implemented as one or more computer-readable or machine-readable storage media. Note that while in the example embodiment of FIG. 6 storage media 1106 is depicted as within computer system 1101A, in some embodiments, storage media 1106 may be distributed within and/or across multiple internal and/or external enclosures of computing system 1101A and/or additional computing systems. Storage media 1106 may include one or more different forms of memory including semiconductor memory devices such as dynamic or static random access memories (DRAMs or SRAMs), erasable and programmable read-only memories (EPROMs), electrically erasable and programmable read-only memories (EEPROMs) and flash memories, magnetic disks such as fixed, floppy and removable disks, other magnetic media including tape, optical media such as compact disks (CDs) or digital video disks (DVDs), BLURAY® disks, or other types of optical storage, or other types of storage devices. Note that the instructions discussed above can be provided on one computer-readable or machine-readable storage medium, or alternatively, can be provided on multiple computer-readable or machine-readable storage media distributed in a large system having possibly plural nodes. Such computer-readable or machine-readable storage medium or media is (are) considered to be part of an article (or article of manufacture). An article or article of manufacture can refer to any manufactured single component or multiple components. The storage medium or media can be located either in the machine running the machine-readable instructions, or located at a remote site from which machine-readable instructions can be downloaded over a network for execution.

In some embodiments, computing system 1100 contains one or more prediction module(s) 1108 that may perform at least a portion of one or more of the method(s) described above. It should be appreciated that computing system 1100 is only one example of a computing system, and that computing system 1100 may have more or fewer components than shown, may combine additional components not depicted in the example embodiment of FIG. 11, and/or computing system 1100 may have a different configuration or arrangement of the components depicted in FIG. 11. The various components shown in FIG. 11 may be implemented in hardware, software, or a combination of both hardware and software, including one or more signal processing and/or application specific integrated circuits.

Further, the steps in the processing methods described herein may be implemented by running one or more functional modules in information processing apparatus such as general purpose processors or application specific chips, such as ASICs, FPGAs, PLDs, or other appropriate devices. These modules, combinations of these modules, and/or their combination with general hardware are all included within the scope of protection of the invention.

Geologic interpretations, models and/or other interpretation aids may be refined in an iterative fashion; this concept is applicable to embodiments of the present methods discussed herein. This can include use of feedback loops executed on an algorithmic basis, such as at a computing device (e.g., computing system 1100, FIG. 11), and/or through manual control by a user who may make determinations regarding whether a given step, action, template, model, or set of curves has become sufficiently accurate for the evaluation of the subterranean three-dimensional geologic formation under consideration.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. Moreover, the order in which the elements of the methods are illustrated and described may be re-arranged, and/or two or more elements may occur simultaneously. The embodiments were chosen and described in order to best explain the principles of the invention and its practical applications, to thereby enable others skilled in the art to best utilize the invention and various embodiments with various modifications as are suited to the particular use contemplated.

What is claimed is:

1. A method for predicting a likelihood that a physical phenomenon will occur in an area of interest at a wellsite, the method comprising:
receiving input parameters for a well in the area of interest;
generating or updating a geomodel based upon the input parameters, wherein the geomodel comprises a first model or a second model, wherein the first model comprises a simulation engine and an intermediary data science engine, and wherein the second model comprises a pre-trained machine-learning model;
predicting a pressure result using the geomodel, wherein the pressure result is based upon the input parameters, wherein the pressure result is predicted by the simulation engine upon completion of a simulation process, and subsequently monitored and checked by the intermediary data science engine in response to the geomodel being the first model, or wherein the pressure result is predicted by the second model run by the intermediary data science engine in response to the geomodel being the second model; and
predicting the likelihood that the physical phenomenon will occur in the future in the area of interest based upon the pressure results, wherein the likelihood that the physical phenomenon will occur is predicted using a third model that is different than the first and second models.

2. The method of claim 1, wherein the input parameters comprise historical physical phenomenon event data, and wherein the historical physical phenomenon event data comprises land subsidence, earthquakes, collapsing of subsurface cavities, compaction of loose deposits, faults, or a combination thereof.

3. The method of claim 2, wherein the likelihood is also based upon the and the historical physical phenomenon event data.

4. The method of claim 1, wherein the input parameters comprise user input data, and wherein the user input data comprises a location of the well, an injection rate into the well, a bottom hole pressure in the well, or a combination thereof.

5. The method of claim 1, wherein the input parameters comprise historical pressure and injection data, and wherein the historical pressure and injection data comprises injection rates into a plurality of wells in the area of interest and bottom hole pressures in the plurality of wells.

6. The method of claim 1, wherein the second model comprises a physics-based neural network that includes a loss function, and wherein the loss function is based upon a data loss and a physics loss.

7. The method of claim 6, wherein the loss function comprises a summation of the data loss and a product, wherein the product comprises the physics loss multiplied by a weighting factor.

8. The method of claim 1, further comprising generating and displaying a heat map based upon the likelihood, wherein the heat map shows the likelihood that the physical phenomenon will occur at a plurality of locations in the area of interest.

9. The method of claim 1, further comprising performing a wellsite action based upon the likelihood to mitigate a risk created by the physical phenomenon occurring.

10. The method of claim 9, wherein the wellsite action comprises varying an injection rate into the well, varying an injection pressure into the well, or drilling a different well elsewhere in the area of interest.

11. A computing system, comprising:
one or more processors; and
a memory system coupled to the one or more processors and comprising one or more non-transitory computer-readable media storing instructions that, when executed by at least one of the one or more processors, cause the computing system to perform operations, the operations comprising:
receiving input parameters for a well in an area of interest, wherein the input parameters comprise historical physical phenomenon event data, user input data, and historical pressure and injection data, wherein the historical physical phenomenon event data comprises land subsidence, earthquakes, collapsing of subsurface cavities, compaction of loose deposits, faults, or a combination thereof, wherein the user input data comprises a location of the well, an injection rate into the well, a bottom hole pressure in the well, or a combination thereof, and wherein the historical pressure and injection data comprises injection rates into a plurality of wells in the area of interest, bottom hole pressures in the plurality of wells, or both;
generating or updating a geomodel based upon the input parameters, wherein the geomodel comprises a proxy machine-learning model, wherein the proxy machine-learning model comprises a pre-trained Py-Torch machine-learning model, wherein the proxy machine-learning model comprises a physics-based neural network that includes a loss function, and wherein the loss function is based upon a data loss and a physics loss;
predicting a pressure result using the geomodel, wherein the pressure result is based upon the input parameters, wherein the pressure result is predicted by the proxy machine-learning model run by a data science engine; and
predicting a likelihood that a physical phenomenon will occur in the future in the area of interest based upon the pressure results and the historical physical phenomenon event data, wherein the likelihood that the physical phenomenon will occur is predicted using a different pre-trained machine-learning model.

12. The computing system of claim 11, wherein the operations further comprise generating heat map based upon the likelihood, wherein the heat map shows the likelihood that the physical phenomenon will occur at a plurality of locations in the area of interest.

13. The computing system of claim 11, wherein the operations further comprise performing a wellsite action based upon the likelihood to mitigate a risk created by the physical phenomenon occurring, wherein the wellsite action comprises varying an injection rate into the well, varying injection pressure into the well, or drilling a different well elsewhere in the area of interest.

14. The computing system of claim 11, wherein the data loss is based upon:
a predicted pressure within the reservoir made by the neural network at a time and a spatial position within a reservoir;
an observed or known pressure within the reservoir at the time and the spatial position.

15. The computing system of claim 14, wherein the physics loss is based upon:
a pressure diffusivity that is related to a permeability, a viscosity, and a porosity of the reservoir;
a Laplacian of a pressure that represents a spatial diffusion of the pressure within the reservoir; and
a number of points used to enforce a partial differential equation in the physics loss.

16. A non-transitory, computer-readable medium storing instructions that, when executed by at least one processor of a computing system, cause the computing system to perform operations, the operations comprising:
receiving input parameters for a well in an area of interest, wherein the input parameters comprise historical physical phenomenon event data, user input data, and historical pressure and injection data, wherein the historical physical phenomenon event data comprises land subsidence, earthquakes, collapsing of subsurface cavities, and compaction of loose deposits, faults, wherein the user input data comprises a location of the well, an injection rate into the well, and a bottom hole pressure in the well, and wherein the historical pressure and injection data comprises injection rates into a plurality of wells in the area of interest and bottom hole pressures in the plurality of wells;
generating or updating a geomodel based upon the input parameters, wherein the geomodel comprises a proxy machine-learning model, wherein the proxy machine-learning model comprises a pre-trained Py-Torch machine-learning model, wherein the proxy machine-learning model comprises a physics-based neural network that includes a loss function, and wherein the loss function is based upon a data loss and a physics loss;
predicting a pressure result using the geomodel, wherein the pressure result is based upon the input parameters, and wherein the pressure result is predicted by the proxy machine-learning model run by a data science engine;
predicting a likelihood that a physical phenomenon will occur in the future in the area of interest based upon the pressure results and the historical physical phenomenon event data, wherein the likelihood that the physical phenomenon will occur is predicted using a different pre-trained machine-learning model;
generating a tree map and a heat map based upon the likelihood, wherein the heat map shows the likelihood that the physical phenomenon will occur at a plurality of locations in the area of interest; and
performing a wellsite action based upon the heat map, the tree map, or both to mitigate a risk created by the physical phenomenon occurring, wherein the wellsite action comprises varying an injection rate, varying injection pressure into the well, or drilling a different well elsewhere in the area of interest.

17. The non-transitory, computer-readable medium of claim 16, wherein the data loss [symbol] _{data} is calculated by:
$${ℒ}_{data} - \frac{1}{N} {\sum }_{i = 1}^{N} {( P ( {t}_{i} , {x}_{i} ) - {P}_{data} ( {t}_{i} , {x}_{i} ) )}^{2}$$
where P(tᵢ,xᵢ) represents a predicted pressure within a reservoir made by the neural network at time tᵢ and spatial position xᵢ within the reservoir, P_{data}(tᵢ,xᵢ) represents an observed or known pressure within the reservoir at the time tᵢ and the spatial position xᵢ, and N represents a number of data points used to calculate the data loss.

18. The non-transitory, computer-readable medium of claim 17, wherein the physics loss [symbol] _{physics} is calculated by:
$${ℒ}_{physics} = \frac{1}{M} {\sum }_{j = 1}^{M} {( \frac{\partial P ( {t}_{j} , {x}_{j} )}{\partial t} - D {∇}^{2} P ( {t}_{j} , {x}_{j} ) )}^{2}$$
where D represents a pressure diffusivity that is related to a permeability, a viscosity, and a porosity within the reservoir, ∇²P(tⱼ, xⱼ) represents a Laplacian that represents a spatial diffusion of the pressure within the reservoir, and M represents a number of points used to enforce a partial differential equation in the physics loss.

19. The non-transitory, computer-readable medium of claim 18, wherein a pressure diffusion is governed by:
$${ℒ}_{total} = {ℒ}_{data} + λ {ℒ}_{physics}$$

20. The non-transitory, computer-readable medium of claim 18, wherein the loss function [symbol] ₜₒₜₐₗ is calculated by:
$$\frac{\partial p}{\partial t} = D {∇}^{2} P .$$
where λ represents a weighting factor that controls a balance between the observed or known pressure and satisfying the pressure diffusion.
